(19) United States
(12) Patent Application Publication
(10) Pub. No.: US 2007/0236301 A1
(43) Pub. Date: Oct. 11, 2007

(54) Inexpensive low phase noise high speed stabilized time base

(76) Inventor: Romi Mayder, San Jose, CA (US)

Correspondence Address: VERIGY, 4700 INNOVATION WAY, BLDG D1, FORT COLLINS, CO, 80528, US

(21) Appl. No.: 11/385,963

(22) Filed: Mar. 21, 2006

(51) Int. Cl. H03B 5/32

(52) U.S. Cl. 331/158

(57) ABSTRACT

A low phase noise high speed stabilized time base uses a crystal resonator that operates directly at a desired high frequency of one hundred to several hundred MHz. An inverted mesa AT-cut quartz crystal meets this criteria. To promote frequency stability the crystal and its oscillator circuit are thermally clamped to a convenient temperature that need be only loosely regulated, say, at about room temperature. In an exemplary ATE setting that already provides a water flow heat removal system whose supply side is 26° C.,±0.5° C., a 400 MHz inverted mesa AT-cut crystal is simply given its own loop within that water supply. Other temperature stabilization techniques for loose regulation, such as Peltier cells, may be used. The result is a high frequency time base having adequate frequency accuracy and stability, but with the extremely low timing jitter of just the crystal resonator, since there is no contributory timing jitter from a frequency multiplying PLL.

### INTRODUCTION AND BACKGROUND

Various types of electronic test equipment require a stable clock signal, or time base. This is particularly true of equipment whose internal architecture relies upon sampling signals of interest and storing their digitized values in memory for subsequent processing. There are at least two reasons why such a time base might need to provide a high speed clock signal (say, one of one hundred to several hundred megahertz). First, there is a saying in the ATE (Automated Test Equipment) industry that “time on the tester is money . . . ”. The import of this is that if the tests for a DUT (Device Under Test) can be concluded more quickly, more parts can be tested with fewer (expensive) testers, and an economic savings realized. Some instances for such ATE are truly large scale systems by any of several measures (‘foot print’ or physical size, power consumption in kilowatts, pounds per square foot of floor strength required, other site environmental requirements, etc.), not to mention their cost (some ATE systems for testing memory devices are expandable, and when fully populated with options can cost well over a million dollars US). Secondly, as progress reveals itself newly developed parts to be tested can themselves operate at ever higher speeds. Since it is desirable to test parts at the speeds at which they will be expected to actually operate, or to sort them according to suitability for operating at different speeds, the ATE that tests the parts needs itself to be able to operate at comparable or higher speeds than is to be expected for the parts under test.

The time base needs also to be stable, at least in the sense that it has reasonable frequency stability (accuracy over time) with low cycle to cycle jitter, or phase noise. Since a given part might be tested in a period of time ranging from a fraction of a second to perhaps a minute or more, actual long term frequency stability of the time base in the strict laboratory sense (e.g., a few parts in 10¹² or 10¹⁴ per day) is not a requirement. Nor is time base of the highest precision needed in testing parts: a time base of, say, 400,000,00X Hz (i.e., known to eight digits) is essentially just as effective as one of 400,000,000.0XX Hz (known to ten digits). That is, a DUT that fails above 350 MHz will fail at both, while one that operates up to 425 MHz will pass at both. Accordingly, we do not find merchant ATE equipped with primary frequency standards of the cesium or rubidium variety: a quartz crystal oscillator is generally quite adequate.

On the other hand, and especially for high speed operation, the jitter in edge placement can often have a great deal to do with whether or not a DUT passes or fails. We may think of jitter in a digital signal (one whose value at stated times is either a logical ONE (TRUE) or logical ZERO (FALSE)) as deviations from ideal locations along a time axis for the signal's transitions. ATE equipment is often expected to be able to measure such jitter, requiring the ability to take a sample of a signal at a selected particular location within a clock cycle, and to do so with considerable resolution. And, not only must ATE measure jitter for output signals produced by a DUT, it generally is expected to supply various stimuli to the DUT to test its ability to tolerate inputs that are less than ideal. Besides varying signal levels and transition times ( ), one of the parameters that can be varied is edge placement for those stimuli, which tests the DUT's susceptibility to jitter on its input signals. Once again, this requires the ability to select a particular location within a clock cycle as the location for an applied transition in a stimulus signal. Various ways are known to accomplish some needed activity at the selected location, and these amount to referencing a programmable delay to an edge in the time base. This is all well and good, but the degree of confidence we have in such arrangements is limited not only by the accuracy of creating the delay, but also by the short term stability of the time base itself. That is, we can't go around purporting to make accurate measurements on a DUT, including ones pertaining to jitter, if the time base we use for orchestrating such tests is itself afflicted by significant jitter.

So, as purveyors of high quality ATE to the electronics industry, while we might not care that our high speed time base does not have the absolute accuracy and long term stability of a laboratory grade standard, we definitely do want its short term drift and phase noise (cycle to cycle jitter) to be so low as to be an insignificant source of error in the tests and measurements made by our ATE.

The usual solution for addressing these concerns is to employ a medium to low frequency crystal oscillator (e.g., in the range of 10-20 MHz), perhaps stabilized either with an oven or other compensatory mechanism based on sensing the temperature of the crystal. When properly accomplished these techniques afford, at the crystal's frequency, suitably accurate frequency and reasonably low levels of phase noise. Unfortunately, most crystals do not operate at the higher frequencies (e.g., 400 MHz, or more) often desired for modern ATE installations. Until recently, crystals whose fundamental frequency was that high had to be so thin that they could not withstand the wire bonding process, or that they would crack during operation.

For operation above about 100 MHz the usual companion solution is to employ a PLL (Phase Locked Loop) as part of a frequency multiplication scheme to get a time base at the desired frequency. This has two disadvantages. First, the multiplication also multiples the phase noise present in the oscillator. Second, the PLL itself is a servo-mechanism that hunts during its operation. Furthermore, any power supply ripple contributes a disturbance to the operation of the servo-mechanism. That is, a PLL adds its own contribution to the phase noise, and that contribution can be quite significant. Indeed, jitter can be subjected to analysis by test equipment designed for that purpose, and it has been found that the multiplication/PLL strategy is prone to introducing both random jitter and pattern dependent jitter. A circuit of this sort can be expected to exhibit timing jitter of perhaps one hundred picoseconds peak-to-peak. As a result, it can be very difficult for a multiplication/PLL technique to provide a stable low phase noise (low timing jitter) high speed time base (say, at 400 MHz) in an ATE setting. But if we don't provide suitably low phase noise, then our ATE machinery cannot be expected to accurately measure the jitter of a DUT, not to mention the limitations imposed on the accuracy of other measurements that might arise from jitter in the time base.

A recently developed inverted mesa AT-cut (and very thin) quartz crystal can have exhibit modes of oscillation that occur directly at the desired frequency of oscillation, while exhibiting excellent low amounts of phase noise, or timing jitter. Unfortunately, the AT cut is not particularly stable with respect to variations in temperature. A typical low cost merchant oscillator unit using one of these crystals is packaged in a metal can for surface mount installation and is expected to operate internally at about the external ambient temperature, which is allowed to range from 0° to 70° C. Over that range the excellent timing jitter is unaffected, but the frequency of operation is allowed to vary by ±100 ppm (parts per million). That is a fairly disgusting variation for an expensive piece of ATE, as well as for certain other applications involving a time base for electronic test equipment.

We need a low phase noise high speed time base of reasonable short term stability and accuracy without the expense and fuss (not to mention the amount of space and the maintenance requirements . . . ) associated with primary standards or even the ‘mere laboratory grade’ stuff. What to do?

### SIMPLIFIED DESCRIPTION

A solution to the problem of creating a low phase noise high speed time base of reasonable short term stability and accuracy is to use a crystal that does operate directly at the desired high frequency, say in the range of one hundred to seven hundred MHz. A recently developed inverted mesa AT-cut quartz crystal meets this criteria. To decrease the influence on frequency of the external ambient environment's temperature to about ±20 ppm the crystal and its oscillator circuit are thermally clamped to a convenient temperature that need be only loosely regulated, say, for example, at about ‘room temperature’ of 26° C.,±0.5° C., which is around 79° F. (It will be noted by those familiar with high stability oven stabilized crystal oscillators that this is a far cry from operation at 70°-80° C. with temperature regulation to a few thousandths of a degree.) In an ATE setting that already provides a ‘cool’ water flow heat removal system whose supply side (upon entry into the thermal environment of one or more DUTs) is 26° C.,±0.5° C., a 400 MHz inverted mesa AT-cut crystal oscillator unit is simply given its own loop in that water supply. Other temperature stabilization techniques for loosely regulating the temperature, such as Peltier cells, also come to mind as suitable mechanisms, but which remain well short of using a precisely controlled high temperature oven. The result is an inexpensive high speed time base having adequate frequency accuracy and stability (it is crystal controlled!), but with timing jitter of less than one picosecond peak-to-peak (no rattle from a PLL).

### BRIEF DESCRIPTION OF THE DRAWINGS

FIG. 1 is a simplified block diagram of an inexpensive low phase noise high speed stabilized time base;

FIG. 2 is a simplified block diagram of the inexpensive low phase noise high speed stabilized time base of FIG. 1 used within an ATE environment, where the loosely controlled temperature environment is provided by flowing water;

FIG. 3 is a simplified block diagram of the inexpensive low phase noise high speed stabilized time base of FIG. 1, where the loosely controlled temperature environment is provided by Peltier cells; and

FIG. 4 is a simplified view of a prior art inverted mesa AT-cut quartz crystal resonator oscillator unit adaptable for use in circuits whose block diagrams resemble those of FIG. 1, 2 or 3.

### DETAILED DESCRIPTION

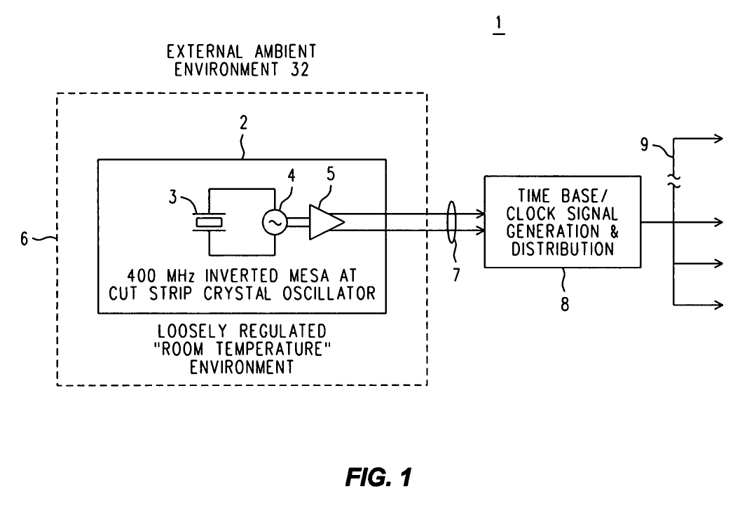

Refer now to FIG. 1, wherein is shown a simplified block diagram 1 of an inexpensive low phase noise high speed stabilized time base. It comprises a high frequency oscillator unit 2 that operates directly at the frequency for the high speed time base, without the need for frequency multiplication circuits and/or phase locked loops. Oscillator unit 2 may have a differential output signal 7 that is coupled to a Time Base/Clock Signal Generator & Distribution circuit 8, from which timing signals 9 are applied to some using device or circuitry (not shown).

Oscillator unit 2 itself may be a merchant assembly, perhaps from a vendor such as Crystek Crystals Corporation of Fort Myers, Fla. It might, for example, be similar to one of their Models CVPD-940 or CVPD-970 3.3 volt LVPECL differential VCXO, whose standard offerings for frequency of operation range from around 78 MHz to about 669 MHz. These voltage controlled oscillators are small (9 by 14 mm, 5 mm high) hermitically sealed metal cans intended for surface mount applications. These oscillators are expected to operate at the temperature of their surrounding ambient environment, and do not include any mechanism to establish or regulate their temperature of operation. So, for example, these Crystek parts have only six electrical terminals: power (3.3 V), power return, a frequency control voltage, and enable/disable input, and two differential output signals. Their operating temperature range is said to be 0° C. to 70° C. (an option of −40° C. to 85° C. is available), with a maximum input current of 80 mA. For all its fine properties, a member of this family of oscillator units is not a miniature oven oscillator with internal heaters! Furthermore, it can be expected to exhibit a ±100 ppm variation in frequency over an operating range of 0° C. to 70° C. for the surrounding ambient environment.

Nevertheless, such a part is a good one for our purpose, for it is also a crystal oscillator that operates directly at the frequency of interest with very low phase noise, or timing jitter (e.g., about one picosecond). In the example of FIG. 1 that frequency is 400 MHz, and it will be readily appreciated that the frequency of interest might be higher or lower, depending upon the crystal selected and its associated oscillator circuitry. As mentioned in the Introduction and Background, excellent short term stability and very low phase noise (timing jitter) is what we seek, while we are prepared to be more relaxed about absolute frequency accuracy and long term stability (as compared to how they would otherwise be viewed by the ‘frequency standards’ professional). Nevertheless, we should like to significantly reduce the ±100 ppm variation in frequency over the operating range of 0° C. to 70° C. We should like to get it down to, say, ±20 ppm, or perhaps even to +10 ppm, but do so without incurring the expense and aggravation of genuine precision regulated high temperature thermal oven.

A good quality crystal oscillator, properly designed and operated, can be expected to exhibit the sort of low timing jitter and good phase noise that we seek, and it is in that connection that we have mentioned the Crystek parts. No doubt other vendors also provide suitable comparable products that would serve as well. The low timing jitter/good phase noise behavior is preserved since the oscillator unit 2 operates directly at a desired frequency of interest, and without the need of frequency multipliers and phase locked loops (that is to say, and also without their attendant rattle!) We also note that, while we admit the possibility of a do-it-yourself oscillator design/assembly, it is recognized that the design of a reliable good quality crystal and its oscillator is an art unto itself, and that suitable merchant parts of modest price are available for purchase.

To continue, the oscillator unit 2 may employ an inverted mesa AT cut strip crystal 3 coupled to an oscillator circuit 4, that in turn drives a buffer amplifier 5 to provide the aforementioned (differential) output signal 7. At the end of this Detailed Description we shall provide some further information about the innards of the oscillator unit 2. At the moment, we are treating it as simply a unitary component (2) within the block diagram 1. (After all, that is what you would get if you simply went out and bought one, as opposed to making your own . . . .) It is in that spirit, then, that we note that oscillator unit 2 is located within (inside, perhaps enclosed by, or maybe simply ‘upon, but well connected to’) a loosely regulated temperature environment 6. It will be further appreciated that the loosely regulated temperature environment 6 is itself located within an external ambient environment 32 (which may be on a chassis within the volume enclosed by a cabinet located on a lab bench, or, on a factory floor). And while we admit that it is unlikely that the temperature of that external ambient environment 32 is as uncontrolled as the natural elements at that location on the planet (i.e., our equipment is probably located within a building or other structure also populated with human beings), the temperature of the external ambient environment 32 (on the chassis) is not itself ‘regulated’ or ‘controlled’ (although there may be an exhaust fan to guard against overheating . . . ).

We shall give in due course some specific examples of how the oscillator unit 2 may be located within a loosely regulated temperature environment 6. At the moment, however, we need to establish what is meant by the term ‘loosely regulated temperature environment.’ ‘Regulated’ is a strong word when used by itself, and what we mean by a ‘loosely regulated temperature’ is one that is controlled only approximately, or alternatively, is one that is made the same as the existing and generally stable temperature of some other medium. In the latter case it is also without further adjustment in response to the oscillator's actual temperature. That is, ‘open loop’ control (in the servo mechanism sense of no feedback) is a form of ‘loose regulation’ in the sense we intend.

To dwell on this idea for a moment, we can say that we don't care as much what the oscillator's temperature is, so long as it stays at about that temperature, say within one or two degrees Centigrade. Plus or minus a half-degree Centigrade is another suitable range. Now, these are actually a fairly wide ranges for a device (the oscillator unit 2) that dissipates no appreciable power, and if one were to fashion a genuine servo loop to control the temperature, such a specification could be easily met in several ways. Indeed, the sensing of temperature and the determination of a corrective control signal are not especially burdensome tasks; their achievement might be as simple as a thermistor, a reference voltage and a few stages of amplification driving a heater. But the overall problem is not that simple. A fictitious tale of product development will help explain.

Suppose we wished to construct a small portable apparatus that was to have a high frequency time base with the properties we have been describing: low phase noise, good short term stability and merely modest actual frequency accuracy. This is readily realized with an inverted mesa strip crystal oscillator operated some convenient temperature. We note that stuff warms up when it is in operation, and so are tempted to provide the oscillator unit with a small source of auxiliary heat that can be added in greater or lesser amounts as needed to arrive at some approximately constant temperature for the oscillator unit. A summer intern picks just above room temperature. This works fine in the air conditioned lab, but a later field trial in the desert during summer reveals the need to put the ‘convenient temperature’ at some inconveniently high value. Ruefully, we remind the intern that it is easier to supply heat than it is to remove it, or keep it out. Now it seems that if we are determined to retain (!?) the same initial strategy (this is a fictitious tale), we would need to put the oscillator unit and its heater in an insulated oven, if for no other reason than to keep the heater from heating up the rest of the apparatus (“What do you mean, the front panel is too hot to touch . . . ?”) and to keep unnecessary power dissipation (and the size of the power supply) at a minimum.

Meanwhile, our colleagues down the hall are developing a family of refrigerator-sized ATE products intended to have the same general time base. A modestly equipped member of this family draws ten kilowatts, and requires a floor that supports two hundred and fifty pounds per square foot. They have (for other, and perhaps obvious, reasons) already solved the problem of how to get rid of all that heat: they used a closed loop water circulation system with either: (a) A fan and a radiator disposed outside a shaded section of the building; or (b) An intermediate heat exchanger connected to some source of cold or sufficiently chilled water, such as a municipal water supply. Something has to determine the temperature of the reused closed loop water, (essentially a thermostat) and while no one particular temperature is thought to be especially better than all others, a variety of considerations combine to suggest ‘room temperature’ as an excellent choice. A consensus emerges that ‘room temperature’ ought to be 26° C.,±0.5° C.

Clearly, the large apparatus already provides its own solution: add the thermal environment of oscillator unit 2 as an item in the path of the freshly chilled water of the re-circulation loop. In the scheme of things for the large apparatus (actually a genuine instance of ATE—the Agilent V5500—intended for testing memory ICs) the expense for doing so is negligible; it is simply to take advantage of what is already at hand for another purpose.

The folks on the large apparatus project find the story of the proposed oven for the small apparatus slightly amusing, in a perverse sort of way. Ordinarily, an oven stabilized crystal oscillator is a fairly expensive item used to obtain a precision time base that has both good short term and good long term stability. They need to stabilize for hours or days before they reach rated specifications (early versions, such as the double-oven HP 104AR took as long as twenty-one days). But a ‘good’ oven oscillator is not needed, and its expense is definitely not wanted, so, . . . , the plan is to build a bad one?The retort of the small apparatus team is that: “A not-so-stable oscillator is being made much more stable for not very much expense.” Also, the inevitable snide remarks about equipping the small apparatus with a tiny radiator and fan at the end of a long hose (when not in use, to be wound up on the rear panel like the cord on a vacuum cleaner) are becoming tiresome to the personnel of the small apparatus project.

The small apparatus (still fictitious, but actually plausible) does present a challenge, however, as it seems we do have to choose between a hot oven on the one hand, and on the other the ability to both heat and cool a small object to maintain its temperature at near ‘room temperature.’ Our distinguished colleagues from down the hall have dissuaded us from using the infernal high temperature oven. However, it does turn out that there is an agreeable solution for the heating and cooling of small objects to maintain a ‘room temperature.’

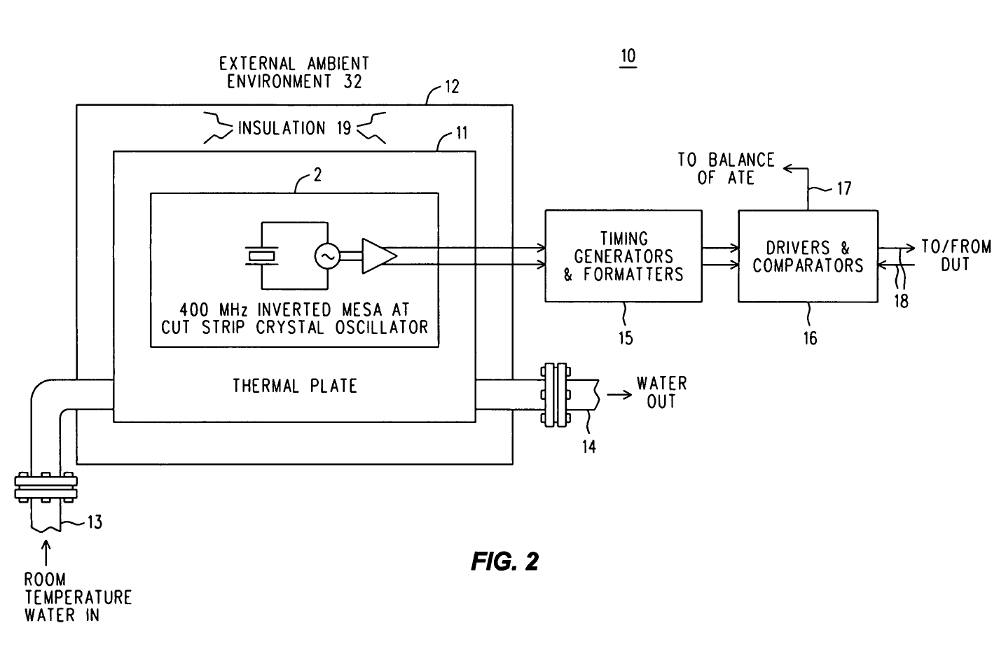

Refer now to FIG. 2, wherein is shown a simplified block diagram 10 where the inexpensive low phase noise high speed time base of FIG. 1 is used within an ATE environment and the loosely controlled temperature environment is provided by flowing water whose temperature has been adjusted to be within some desired range. In this arrangement the oscillator unit 2 drives circuitry 15 having Timing Generators and Formatters, which is in turn coupled to circuitry 16 having Drivers and Comparators for which various signals 18 are applied to, and received from, a DUT 19 under test. Circuitry 16 also produces various signals 17 that are sent to the balance of the ATE (to, for example, make a record of test results). This is an extremely abbreviated view of what ATE is like, and capable of, but is sufficient to inform us generally about the role played by the time base 2.

Considering now the time base 2, we note that it is located within a low thermal resistance environment, which may be accomplished by mounting the oscillator unit 2 to a suitable thermal plate 11 having a low thermal resistance (e.g., copper or aluminum). The thermal plate 11 includes a water tight passage or passages therethrough having an inlet 13 and an outlet 14. Chilled water whose temperature has previously been controlled to be, for example only, 26° C.,±0.5° C., is applied to the inlet 13, while the discharge from the outlet 14 is sent back to the return side of the water supply (not shown). The flow rate of the water through the thermal plate 11 is adjusted by design to be sufficient (once the water supply itself is at temperature) to readily warm the oscillator unit 2 to about 26° C. independently of a cooler ambient temperature, as well as to cool it to about 26° C. despite a warmer ambient temperature and power dissipation by the oscillator unit 2 itself. Given that the oscillator unit 2 is pretty small (the Crystek product mentioned above is 9×4×5 mm) and that its power dissipation is barely a quarter of a watt, no significant additional capacity is required from the recirculating water supply. A system that can remove twenty kilowatts from a fully loaded ATE system won't be bothered by an extra quarter of a watt!

Nevertheless, it remains good practice to enclose the oscillator unit 2 within a housing or enclosure 12, and to place a layer of thermal insulation 19 between the outside of thermal plate/oscillator combination and the inside of the enclosure. Between the thermal plate and the insulation 19 we can be assured that after a brief period of equilibration the oscillator unit 2 is operating at the temperature of the water supplied at the inlet 13. On the other hand, it will be appreciated that insulation 19 and the enclosure 12 are not essential to loose regulation of the temperature for oscillator unit 2. If need be the capacity of the thermal plate 11 (thickness) and its recirculating water supply (rate of flow) to add and remove heat could be increased to several watts, or to even several tens of watts, before failure to maintain ‘loose regulation’ would likely become an issue. It is more that the incremental price of the enclosure 12 and the insulation 11 is actually rather low, while the peace of mind of knowing that the potential influence of changing environmental temperatures on the oscillator unit 2 is simply no longer an issue of significance, is itself a thing of definite value. (That is, owing to judicious overkill, the issue has been RESOLVED!)

The recirculating water (which might be another fluid) is conditioned to have a temperature of 26° C.,±0.5° C., which as industrial control of temperature goes is not particularly precise (and the actual value and its range chosen are somewhat arbitrary). Furthermore, the temperature of the oscillator unit 2 is only clamped to that value through a passive low thermal resistance path (plate 11), and is not the subject of a servo loop that senses the oscillator's temperature. Thus, the arrangement shown in FIG. 2 satisfies our earlier definition of a ‘loosely regulated temperature environment,’ and can be expected to produce a frequency variation on the order of ±20 ppm or ±10 ppm, depending principally on how well regulated is the temperature of the re-circulating water. The effect on frequency of changes in the ambient environment's temperature are generally insignificant, especially if the oscillator unit is insulated by insulation layer 19.

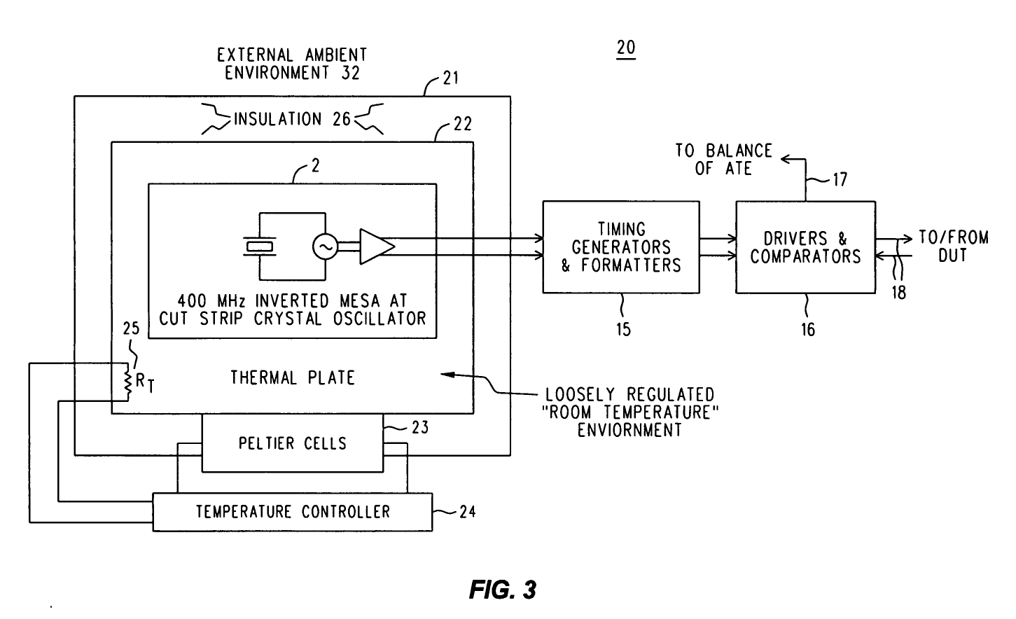

Refer now to FIG. 3, wherein is shown a block diagram 20 similar to that of FIG. 2, save that the loose regulation of the oscillator unit's temperature is achieved through the use of Peltier cells 23. As is well known, Peltier cells exhibit the property of warming on one side while cooling on the other when a DC current is sent through the cell. Reversing the direction of the current will reverse the sides for heating and cooling. One side of the Peltier cells 23 is thermally coupled to the thermal plate 22 (or perhaps, simply to the case of the oscillator unit 2 and there is no thermal plate . . . ), while the other side is exposed to an environment that can accept heat (the ‘outer’ or ‘ambient’ environment). Peltier cells are sometimes assisted by small fans, which, given the size of a Crystek part, would likely be unnecessary. A temperature sensing element R_{T} 25 (e.g., a thermistor) informs a Temperature Controller 24 that in turn drives the Peltier cells 23 with a reversible current to loosely maintain the temperature of the sensor (and thus of the oscillator unit 2) at about a selected set point, as assisted by an optional layer of insulation 26 within an enclosure 21. Since we are interested in only loose regulation, the Temperature Controller 24 can be a simple affair, and the size of the Peltier cells can be relatively small. One could even replace R_{T} 25 with a suitable bi-metal spring type thermostat and the Temperature Controller 24 with fixed voltage power supplies controlled by contact closures in the thermostat. For example, there are known bi-metal thermostats that operate separate heating and air conditioning units at individually selectable set points, while excluding the possibility of activating both at once. However, it is not clear that the cost of such a mechanical solution is actually less than that of the corresponding electronic one, which, it will also be noted, is both more reliable and less susceptible to mis-adjustment.

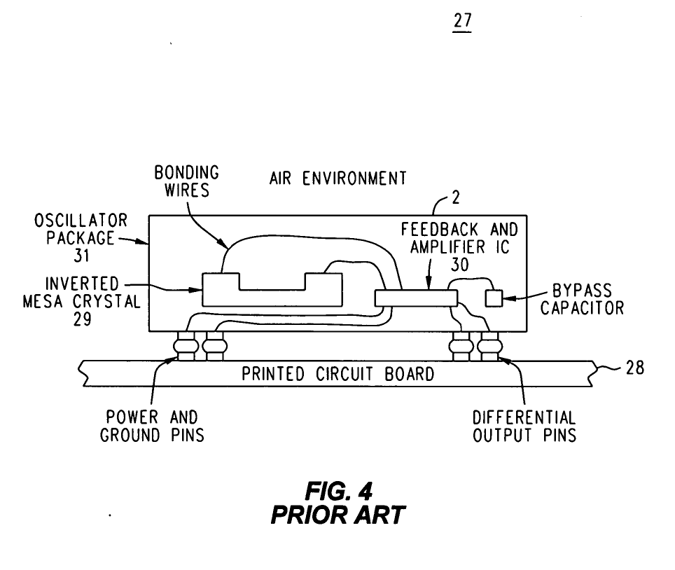

Refer now to FIG. 4, wherein is shown a simplified cutaway side view 27 of a prior art oscillator unit 2 of the sort we are interested in, and which has been attached to a printed circuit board 28 using surface mount techniques. In particular, view 27 may be taken as representative of the general nature of the aforementioned family of parts from the Crystek Crystals Corporation, and it may well be representative of parts from other vendors, as well. Broadly speaking, the oscillator unit 2 includes an inverted mesa crystal 29, which may be of the AT cut, and whose fundamental mode of piezoelectric excitation occurs at the desired high frequency (say, in the range of about 80 or 100 MHz to about 800 MHz). Also included is oscillator circuitry (30) having amplification, feedback, and output buffering. The inverted mesa crystal 29 is, of course, the principal resonant element that determines the frequency and stability of oscillation.

A few remarks are perhaps in order concerning the inverted mesa style of crystal. A ‘thick’ AT cut blank has bonding wires applied and is mounted upon a substrate, after which the center portion of the blank is etched away with an argon ion beam to produce a piezoelectric resonance at the desired high frequency. The result is a very thin central section of quartz which would not withstand further handling. If such a thin crystal were attempted with an ordinary shape, it would be very prone to cracking during operation, even if it were successfully mounted without being broken.

The oscillator circuitry and its quartz resonator are enclosed in a package (typically a metal can) 31. No thermal stabilization is included within the package 31, as the entire oscillator is expected to operate successfully at whatever the ambient temperature is present in the environment immediately external to the oscillator unit 2. For example, the aforementioned Crystek parts are specified to operate over a range of 0° to 70° C. with a permissible variation in frequency of ±100 ppm.

I claim:

1. A circuit for generating a clock signal, the circuit comprising:
an inverted mesa AT-cut quartz crystal resonator;
an oscillator circuit coupled to the inverted mesa AT-cut quartz crystal resonator, oscillating at the fundamental frequency of the inverted mesa AT-cut quartz crystal resonator, and having an output stage producing a clock signal at the fundamental frequency of the inverted mesa AT-cut quartz crystal resonator; and
the inverted mesa AT-cut quartz crystal resonator and the oscillator circuit thermally coupled to an environment having a loosely controlled temperature and that is different from an external ambient environment containing the circuit.

2. A circuit as in claim 1 wherein the clock signal is at least 100 MHz.

3. A circuit as in claim 1 wherein the environment having a loosely controlled temperature comprises a water flow heat removal system.

4. A circuit as in claim 3 wherein the water flow heat removal system is part of an ATE system and also removes heat from DUTs.

5. A circuit as in claim 1 wherein the environment having a loosely controlled temperature comprises at least one Peltier cell.

6. A circuit as in claim 1 wherein the loosely controlled temperature is about 26° C.

7. A circuit as in claim 1 wherein the external ambient environment is allowed to vary over a range of about 40° F.

8. A circuit as in claim 1 wherein the change in clock signal frequency as a function of the loosely controlled temperature is in the range of about ±20 ppm to ±10 ppm.

9. A circuit as in claim 1 wherein the circuit further comprises thermal insulation disposed between the circuit and the external ambient environment containing the circuit.
